(19) United States
(12) Patent Application Publication
(10) Pub. No.: US 2019/0165261 A1
(43) Pub. Date: May 30, 2019

(54) MAGNETIC MEMORY DEVICE AND METHOD OF FABRICATING THE SAME

(71) Applicant: SAMSUNG ELECTRONICS CO., LTD., Suwon-si (KR)

(72) Inventors: Sang-Kuk KIM, Seongnam-si (KR); Oik KWON, Yongin-si (KR); Dongkyu LEE, Suwon-si (KR); Kyungil HONG, Suwon-si (KR)

(73) Assignee: SAMSUNG ELECTRONICS CO., LTD., Suwon-si (KR)

(21) Appl. No.: 16/009,556

(22) Filed: Jun. 15, 2018

(30) Foreign Application Priority Data
Nov. 28, 2017 (KR) 10-2017-0160001

(51) Int. Cl. H01L 43/12; H01L 27/22; H01L 43/02

(52) U.S. Cl. CPC H01L 43/12; H01L 43/02; H01L 27/222

(57) ABSTRACT

A method of fabricating a magnetic memory device may include forming a magnetic tunnel junction layer on a substrate, sequentially forming a top electrode pattern and a mask pattern on the magnetic tunnel junction layer, patterning the magnetic tunnel junction layer using the mask pattern and the top electrode pattern as a first etch mask to form a magnetic tunnel junction pattern, forming a protection layer on side surfaces of the mask pattern, the top electrode pattern, and the magnetic tunnel junction pattern, the protection layer being extended to cover a first top surface of the mask pattern, removing a portion of the protection layer on the first top surface of the mask pattern to expose the first top surface of the mask pattern, and removing the mask pattern to expose a second top surface of the top electrode pattern.

### CROSS-REFERENCE TO RELATED APPLICATION

This application claims priority from Korean Patent Application No. 10-2017-0160001, filed on Nov. 28, 2017 in the Korean Intellectual Property Office, the disclosure of which is incorporated herein in its entirety by reference.

### BACKGROUND

### 1. Field

Apparatuses and methods consistent with example embodiments relate to a magnetic memory device and a method of fabricating the same, and in particular, to a magnetic memory device including a magnetic tunnel junction and a method of fabricating the same.

### 2. Description of the Related Art

Due to an increasing demand for electronic devices with increased speed and/or reduced power consumption, semiconductor devices require faster operating speeds and/or lower operating voltages. Magnetic memory devices have been suggested to satisfy such requirements. For example, the magnetic memory device can provide technical advantages, such as reduced latency and/or non-volatility. As a result, the magnetic memory devices are emerging as next-generation memory devices.

The magnetic memory device includes a magnetic tunnel junction (MTJ) pattern. The MTJ pattern may include two magnetic layers and an insulating layer interposed therebetween. Resistance of the MTJ pattern varies depending on magnetization directions of the magnetic layers. For example, the resistance of the MTJ pattern is higher when magnetization directions of the magnetic layers are anti-parallel to each other than when they are parallel to each other. Such a difference in resistance can be used for data storing operations of the magnetic memory device.

However, more research is still needed to mass-produce the magnetic memory device and satisfy demands for the magnetic memory device with higher integration density and lower power consumption properties.

### SUMMARY

One or more example embodiments provide a method of easily etching a magnetic tunnel junction layer using an ion beam, a method of fabricating a magnetic memory device using the same, and a magnetic memory device fabricated thereby.

An example embodiment of the present disclosure provide a method of easily removing a conductive etch residue in a process of fabricating a magnetic memory device and a magnetic memory device fabricated thereby.

According to an aspect of an example embodiment, a method of fabricating a magnetic memory device may include forming a magnetic tunnel junction layer on a substrate; sequentially forming a top electrode pattern and a mask pattern on the magnetic tunnel junction layer; patterning the magnetic tunnel junction layer using the mask pattern and the top electrode pattern as a first etch mask to form a magnetic tunnel junction pattern; forming a protection layer on side surfaces of the mask pattern, the top electrode pattern, and the magnetic tunnel junction pattern, the protection layer being extended to cover a first top surface of the mask pattern; removing a portion of the protection layer on the first top surface of the mask pattern to expose the first top surface of the mask pattern; and removing the mask pattern to expose a second top surface of the top electrode pattern.

According to an aspect of an example embodiment, a method of fabricating a magnetic memory device may include sequentially forming a magnetic tunnel junction layer, a top electrode layer, and a mask layer on a substrate, the top electrode layer being interposed between the magnetic tunnel junction layer and the mask layer; forming a preliminary mask pattern on the mask layer; patterning the mask layer using the preliminary mask pattern as a first etch mask to form a mask pattern; removing the preliminary mask pattern; and patterning the top electrode layer and the magnetic tunnel junction layer using the mask pattern as a second etch mask. The mask pattern may be removed during the patterning the top electrode layer and the magnetic tunnel junction layer.

According to an aspect of an example embodiment, a magnetic memory device may include a lower interlayered insulating layer disposed on a substrate; data storage structures disposed on the lower interlayered insulating layer, each of the data storage structures including a bottom electrode pattern, a magnetic tunnel junction pattern, and a top electrode pattern, which are sequentially stacked on the lower interlayered insulating layer; conductive contacts provided on the data storage structures; a protection layer covering a first side surface of each of the data storage structures; and an upper interlayered insulating layer provided on the lower interlayered insulating layer to cover the data storage structures and the conductive contacts. The protection layer may be interposed between the first side surface of each of the data storage structures and the upper interlayered insulating layer and may extend to cover a portion of a second side surface of each of the conductive contacts.

### BRIEF DESCRIPTION OF THE DRAWINGS

The above and/or other aspects will be more clearly understood from the following description of example embodiments, taken in conjunction with the accompanying drawings in which:

FIG. 1 is a flowchart illustrating a method of fabricating a magnetic memory device according to an example embodiment;

FIGS. 2 to 10 are sectional views illustrating a method of fabricating a magnetic memory device according to an example embodiment;

FIGS. 11 to 13 are sectional views illustrating a method of fabricating a magnetic memory device according to an example embodiment;

FIG. 14 is a flowchart illustrating a method of fabricating a magnetic memory device according to an example embodiment;

FIGS. 15 to 18 are sectional views illustrating a method of fabricating a magnetic memory device according to an example embodiment;

FIGS. 19 and 20 are sectional views illustrating a method of fabricating a magnetic memory device according to an example embodiment;

FIG. 21 is a plan view of a magnetic memory device fabricated by a method according to an example embodiment;

FIGS. 22 and 23 are sectional views illustrating examples of a magnetic tunnel junction pattern of a magnetic memory device fabricated by a method according to an example embodiment; and

FIG. 24 is a circuit diagram illustrating a unit memory cell of a magnetic memory device fabricated by a method according to an example embodiment.

### DETAILED DESCRIPTION

Reference will now be made in detail to example embodiments, with reference to the accompanying drawings.

The figures are intended to illustrate the general characteristics of methods, structure and/or materials utilized in example embodiments and to supplement the written description provided below. These drawings are not, however, drawn to scale and may not precisely reflect the precise structural or performance characteristics of any given example embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature. It will be apparent that though the terms “first,” “second,” “third,” etc. may be used herein to describe various members, components, regions, layers, and/or sections, these members, components, regions, layers, and/or sections should not be limited by these terms. These terms are only used to distinguish one member, component, region, layer, or section from another region, layer, or section. Thus, a first member, component, region, layer, or section discussed below could be termed a second member, component, region, layer, or section without departing from the teachings of the example embodiments.

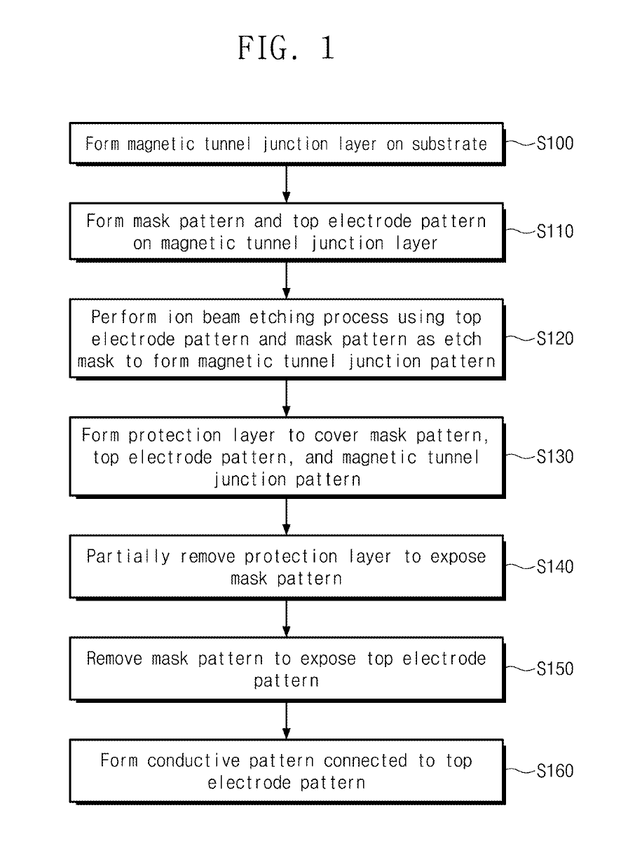

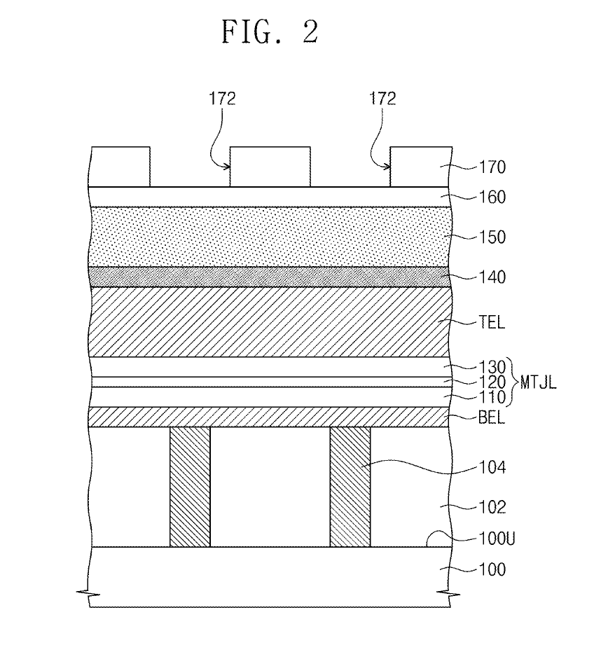

FIG. 1 is a flowchart illustrating a method of fabricating a magnetic memory device according to an example embodiment. FIGS. 2 to 10 are sectional views illustrating a method of fabricating a magnetic memory device according to an example embodiment.

Referring to FIGS. 1 and 2, a lower interlayered insulating layer 102 may be formed on a substrate 100. The substrate 100 may be a semiconductor substrate (e.g., silicon, silicon-on-insulator (SOI), silicon germanium (SiGe), germanium (Ge), and/or gallium arsenide (GaAs) wafers). Selection elements may be formed on the substrate 100. The selection elements may be field effect transistors or diodes. The lower interlayered insulating layer 102 may be formed to cover the selection elements. The lower interlayered insulating layer 102 may have a single- or multi-layered structure and may be formed of oxide, nitride, and/or oxynitride.

Lower contact plugs 104 may be formed in the lower interlayered insulating layer 102. Each of the lower contact plugs 104 may be provided to penetrate the lower interlayered insulating layer 102 and may be connected to the substrate 100. As an example, each of the lower contact plugs 104 may be connected to one of terminals of a corresponding one of the selection elements. The lower contact plugs 104 may be formed of or include doped semiconductor materials (e.g., doped silicon), metals (e.g., tungsten, titanium, and/or tantalum), conductive metal nitrides (e.g., titanium nitride, tantalum nitride, and/or tungsten nitride), and/or metal-semiconductor compounds (e.g., metal silicide).

A bottom electrode layer BEL and a magnetic tunnel junction layer MTJL may be sequentially formed on the lower interlayered insulating layer 102 (operation S100). The bottom electrode layer BEL may be formed of or include at least one conductive metal nitride (e.g., titanium nitride or tantalum nitride). The bottom electrode layer BEL may be formed by a sputtering process, a chemical vapor deposition process, or an atomic layer deposition process. The magnetic tunnel junction layer MTJL may include a first magnetic layer 110, a tunnel barrier layer 120, and a second magnetic layer 130, which are sequentially stacked on the bottom electrode layer BEL. Each of the first magnetic layer 110 and the second magnetic layer 130 may include at least one magnetic layer. Materials for the first magnetic layer 110 and the second magnetic layer 130 will be described in more detail below. The tunnel barrier layer 120 may be formed of or include magnesium oxide, titanium oxide, aluminum oxide, magnesium-zinc oxide, and/or magnesium-boron oxide. Each of the first magnetic layer 110, the tunnel barrier layer 120, and the second magnetic layer 130 may be formed by a physical vapor deposition process or a chemical vapor deposition process.

A top electrode layer TEL, a mask layer 140, and a first preliminary mask layer 150 may be sequentially formed on the magnetic tunnel junction layer MTJL. The top electrode layer TEL may be formed of or include metals (e.g., Ta, W, Ru, or Ir) and/or conductive metal nitrides (e.g., TiN). The top electrode layer TEL may be formed by a sputtering process, a chemical vapor deposition process, or an atomic layer deposition process. The mask layer 140 may be formed of or include a material that is selected from the group consisting of metal oxides, metal nitrides, and carbon-containing materials and is different from that of the top electrode layer TEL. The mask layer 140 may be formed by a sputtering process, a chemical vapor deposition process, or an atomic layer deposition process. A thickness of each of the top electrode layer TEL and the mask layer 140 may be a measure in a direction perpendicular to a top surface 100U of the substrate 100. The mask layer 140 may be formed to have a thickness that is less than that of the top electrode layer TEL. The first preliminary mask layer 150 may be formed of or include a spin-on-hardmask (SOH) material (e.g., a carbon-containing material).

A photoresist pattern 170 may be formed on the first preliminary mask layer 150. An anti-reflection layer 160 may be interposed between the first preliminary mask layer 150 and the photoresist pattern 170. The photoresist pattern 170 may be provided to have a plurality of openings 172 defining positions and shapes of magnetic tunnel junction patterns to be described below. The anti-reflection layer 160 may be formed of or include, for example, silicon oxynitride.

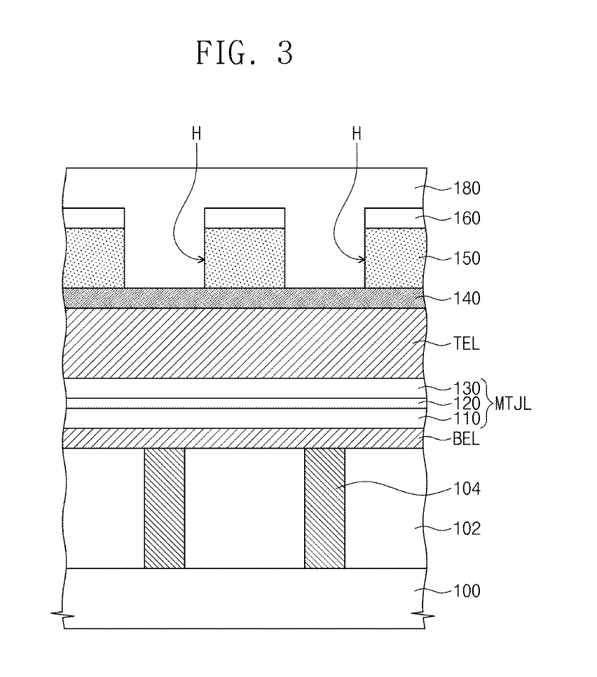

Referring to FIG. 3, the anti-reflection layer 160 and the first preliminary mask layer 150 may be etched using the photoresist pattern 170 as an etch mask. Accordingly, a plurality of holes H may be formed in the anti-reflection layer 160 and the first preliminary mask layer 150. Each of the plurality of holes H may be formed to penetrate the anti-reflection layer 160 and the first preliminary mask layer 150 and thereby to expose a top surface of the mask layer 140. A position and a shape of each of the holes H may be determined by a corresponding one of the openings 172. The photoresist pattern 170 may be removed after the etching of the anti-reflection layer 160 and the first preliminary mask layer 150. Thereafter, a second preliminary mask layer 180 may be formed on the anti-reflection layer 160 to fill the plurality of holes H. The second preliminary mask layer 180 may be formed of or include, for example, silicon oxide.

Referring to FIGS. 1, 4, and 5, mask patterns 142 and top electrode patterns TE may be formed on the magnetic tunnel junction layer MTJL (operation S110).

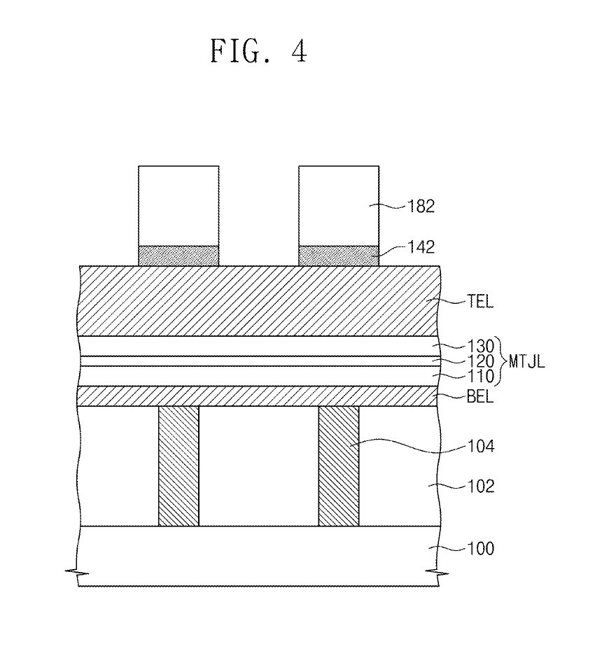

Referring to FIG. 4, second preliminary mask patterns 182 may be formed on the mask layer 140. The formation of the second preliminary mask patterns 182 may include planarizing the second preliminary mask layer 180 to expose the anti-reflection layer 160 and removing the anti-reflection layer 160 and the first preliminary mask layer 150. The planarization of the second preliminary mask layer 180 may be performed using, for example, an etch-back process. The removal of the anti-reflection layer 160 and the first preliminary mask layer 150 may be performed using, for example, an ashing and/or strip process. The second preliminary mask patterns 182 may define positions and shapes of magnetic tunnel junction patterns, which will be described below. The mask layer 140 may be etched using the second preliminary mask patterns 182 as an etch mask, and as a result, the mask patterns 142 may be formed on the top electrode layer TEL.

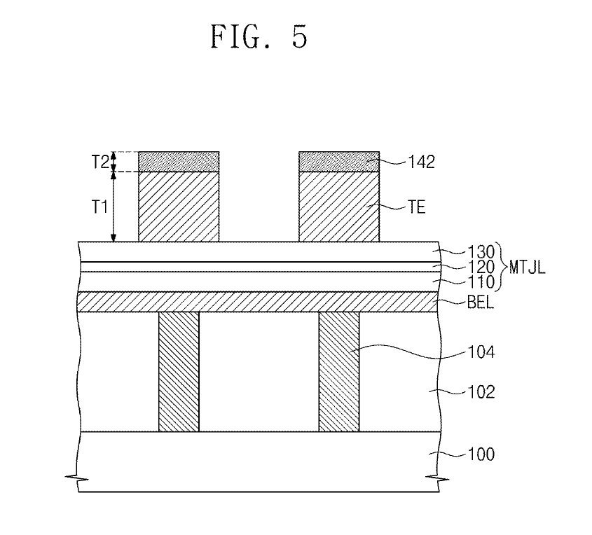

Referring to FIG. 5, the top electrode layer TEL may be etched using the second preliminary mask patterns 182 and the mask patterns 142 as an etch mask. Accordingly, the top electrode patterns TE may be formed on the magnetic tunnel junction layer MTJL. In some example embodiments, the second preliminary mask patterns 182 may be removed during the etching process on the top electrode layer TEL. In certain example embodiments, unlike what is illustrated in the drawings, after the etching process on the top electrode layer TEL, a portion of each of the second preliminary mask patterns 182 may remain on a corresponding one of the mask patterns 142. Each of the top electrode patterns TE may be formed to have a first thickness T1, and each of the mask patterns 142 may be formed to have a second thickness T2 that is less than the first thickness T1. The mask patterns 142 may be provided on the top electrode patterns TE, respectively.

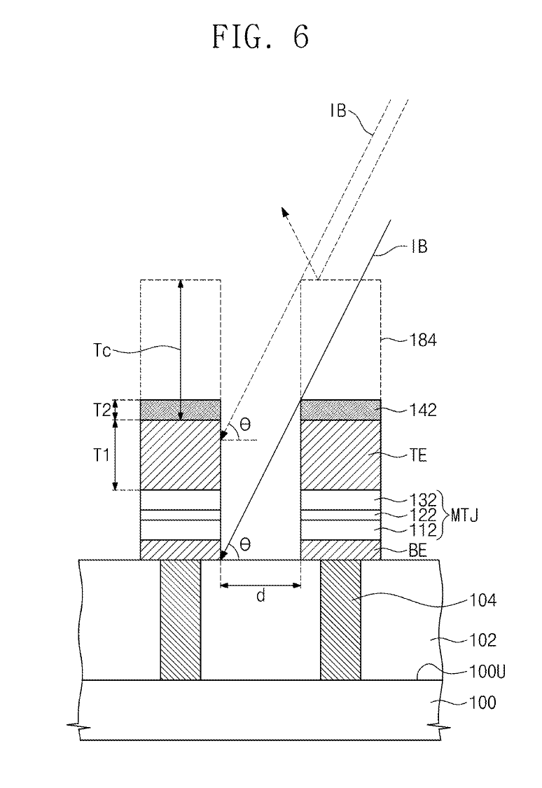

Referring to FIGS. 1 and 6, an ion beam etching process using the top electrode patterns TE and the mask patterns 142 as an etch mask may be performed to form magnetic tunnel junction patterns MTJ and bottom electrode patterns BE (operation S120). Any remaining portion of each of the second preliminary mask patterns 182 on a corresponding one of the mask patterns 142 may be removed during the ion beam etching process.

The ion beam etching process may include irradiating an ion beam IB onto the substrate 100. The ion beam IB may be irradiated at an angle to the top surface 100U of the substrate 100. The ion beam IB may include ions of inert gas (e.g., positive argon ions (Ar⁺)). The magnetic tunnel junction layer MTJL and the bottom electrode layer BEL may be sequentially patterned by the ion beam etching process using the top electrode patterns TE and the mask patterns 142 as the etch mask. Thus, the magnetic tunnel junction patterns MTJ may be formed on the lower interlayered insulating layer 102, and the bottom electrode patterns BE may be formed below the magnetic tunnel junction patterns MTJ, respectively. The bottom electrode patterns BE may be provided on the lower interlayered insulating layer 102 and may be connected to the lower contact plugs 104, respectively. Each of the magnetic tunnel junction patterns MTJ may include a first magnetic pattern 112, a tunnel barrier pattern 122, and a second magnetic pattern 132, which are sequentially stacked on a corresponding one of the bottom electrode patterns BE. The first magnetic pattern 112 and the second magnetic pattern 132 may be spaced apart from each other with the tunnel barrier pattern 122 interposed therebetween. The first magnetic pattern 112, the tunnel barrier pattern 122, and the second magnetic pattern 132 will be described in more detail below.

The top electrode patterns TE may be formed of or include one or more materials, which are selected to have an etch selectivity with respect to the magnetic tunnel junction layer MTJL during the ion beam etching process. In the present disclosure, the term “etch selectivity” means that two elements under consideration have different etch rates from each other. Thus, a high etch selectivity may mean that the difference between the respective etch rates of the elements is great. During the ion beam etching process, an etch rate of the top electrode patterns TE may be lower than an etch rate of the magnetic tunnel junction layer MTJL. The top electrode patterns TE may be formed of or include metals (e.g., Ta, W, Ru, or Ir) and/or conductive metal nitrides (e.g., TiN).

The mask patterns 142 may be formed of or include one or more materials, which are selected to have an etch selectivity with respect to the magnetic tunnel junction layer MTJL during the ion beam etching process. In addition, the mask patterns 142 may be formed of or include a material whose etch selectivity with respect to the magnetic tunnel junction layer MTJL is higher than that of the top electrode patterns TE, during the ion beam etching process. For example, an etch selectivity of the mask patterns 142 to the magnetic tunnel junction layer MTJL may be higher than that of the top electrode patterns TE to the magnetic tunnel junction layer MTJL. As an example, during the ion beam etching process, an etch rate of the mask patterns 142 may be lower than the etch rate of the top electrode patterns TE. The mask patterns 142 may be formed of or include metal oxides (e.g., aluminum oxide), metal nitrides (e.g., aluminum nitride), and/or carbon-containing materials. The second thickness T2 of the mask patterns 142 may be less than the first thickness T1 of the top electrode patterns TE.

In certain example embodiments, conductive etch residue may be produced during the ion beam etching process and may be re-deposited on the magnetic tunnel junction patterns MTJ and the lower interlayered insulating layer 102 therebetween. In the case where the conductive etch residue is re-deposited on side surfaces of the magnetic tunnel junction patterns MTJ, an electric short circuit may be formed between the first magnetic pattern 112 and the second magnetic pattern 132. To remove the re-deposited conductive etch residue from the side surfaces of the magnetic tunnel junction patterns MTJ, the ion beam IB may be irradiated onto the top surface 100U of the substrate 100 at a relatively small angle θ (for example, an angle θ of less than 60 degrees).

According to the conventional technology, mask patterns 184 having a thickness Tc greater than the first thickness T1 may be formed on the top electrode patterns TE, and in this case, the top electrode patterns TE and the conventional mask patterns 184 may be used as an etch mask during the ion beam etching process. However, to increase an integration density of a magnetic memory device, it is necessary to reduce a pitch of the magnetic tunnel junction patterns MTJ or a distance d between the magnetic tunnel junction patterns MTJ, and in this case, the ion beam IB irradiated at the relatively small angle θ may be blocked by the conventional mask patterns 184, as shown in FIG. 6. Thus, an intensity of the ion beam IB to be irradiated onto the magnetic tunnel junction patterns MTJ may be too small to remove the conductive etch residue. Furthermore, in the case where the conventional mask patterns 184, which have the thickness Tc greater than the first thickness T1, are used as the etch mask for the ion beam etching process, the conventional mask patterns 184 may lead to causing a shadowing effect of blocking the ion beam IB, as shown in FIG. 6. That is, there may be various difficulties in the ion beam etching process for etching the magnetic tunnel junction layer MTJL and the bottom electrode layer BEL.

According to an example embodiment, the mask patterns 142 may be formed to have the second thickness T2 that is less than the first thickness T1 of the top electrode patterns TE. In this case, even when the distance d between the magnetic tunnel junction patterns MTJ is reduced and the ion beam IB is irradiated at the relatively small angle θ, it may be possible to provide sufficiently high intensity of the ion beam IB into a space between the magnetic tunnel junction patterns MTJ. Thus, it may be possible to effectively and easily remove the conductive etch residue. Furthermore, it may be possible to prevent or prevent the ion beam IB from being blocked by the mask patterns 142 during the ion beam etching process. Thus, it may be possible to effectively and easily etch the magnetic tunnel junction layer MTJL and the bottom electrode layer BEL through the ion beam etching process.

In addition, the mask patterns 142 may be formed of or include a material, which is higher than the top electrode patterns TE in terms of an etch selectivity with respect to the magnetic tunnel junction layer MTJL during the ion beam etching process. In this case, it may be possible to stably etch the magnetic tunnel junction layer MTJL and the bottom electrode layer BEL during the ion beam etching process.

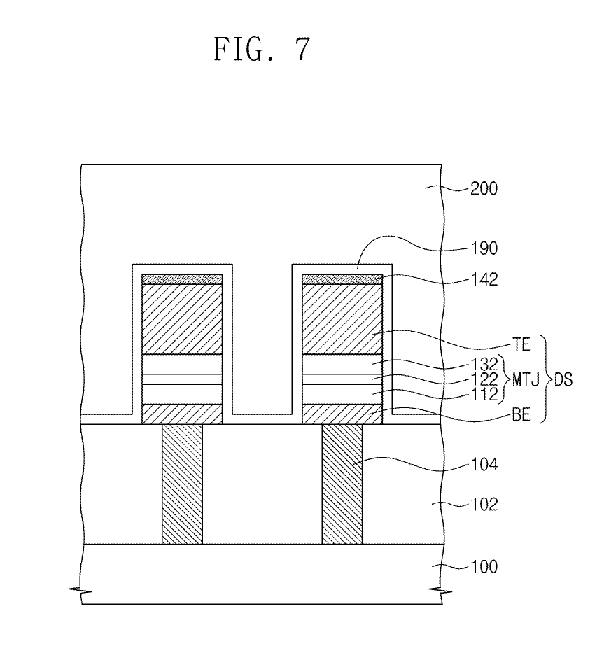

Referring to FIGS. 1 and 7, after the ion beam etching process, at least a portion of each of the mask patterns 142 may remain on a corresponding one of the top electrode patterns TE. Each of the bottom electrode patterns BE, each of the magnetic tunnel junction patterns MTJ, and each of the top electrode patterns TE may be referred to as “a data storage structure DS.”

A protection layer 190 may be formed on the lower interlayered insulating layer 102 to cover the mask patterns 142, the top electrode patterns TE, the magnetic tunnel junction patterns MTJ, and the bottom electrode patterns BE (operation S130). The protection layer 190 may be formed to conformally (e.g., without altering the shapes, angles, etc. of underlying structure) cover side surfaces of the mask patterns 142, side surfaces of the top electrode patterns TE, side surfaces of the magnetic tunnel junction patterns MTJ, and side surfaces of the bottom electrode patterns BE. In other words, the protection layer 190 may be formed to conformally cover the side surface of each of the mask patterns 142 and the side surface of the data storage structure DS. The protection layer 190 may be extended to cover the top surface of each of the mask patterns 142 and to cover a top surface of the lower interlayered insulating layer 102 between the magnetic tunnel junction patterns MTJ. The protection layer 190 may be formed of or include nitride (e.g., silicon nitride).

An upper interlayered insulating layer 200 may be formed on the protection layer 190 to cover the mask patterns 142, the top electrode patterns TE, the magnetic tunnel junction patterns MTJ, and the bottom electrode patterns BE. The protection layer 190 may be interposed between each of the mask patterns 142 and the upper interlayered insulating layer 200 and between the data storage structure DS and the upper interlayered insulating layer 200. The protection layer 190 may extend horizontally between the magnetic tunnel junction patterns MTJ to be interposed between the top surface of the lower interlayered insulating layer 102 and the upper interlayered insulating layer 200. The upper interlayered insulating layer 200 may have a single- or multi-layered structure and may be formed of oxide, nitride, and/or oxynitride.

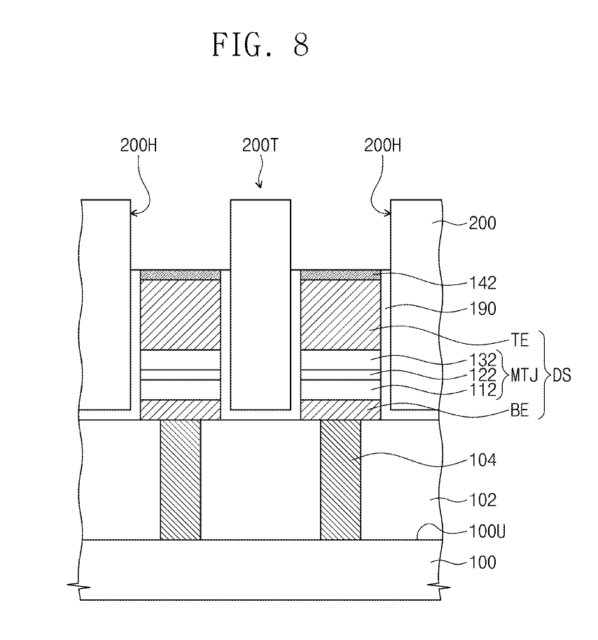

Referring to FIGS. 1 and 8, the upper interlayered insulating layer 200 and the protection layer 190 may be partially removed to expose the mask patterns 142 (operation S140). For example, a trench 200T and contact holes 200H may be formed in the upper interlayered insulating layer 200. The trench 200T and the contact holes 200H may be formed by partially etching the upper interlayered insulating layer 200. The trench 200T may be formed to extend in a direction parallel to the top surface 100U of the substrate 100, and each of the contact holes 200H may be formed to extend from the trench 200T in a direction toward the substrate 100. Each of the contact holes 200H may be formed to expose the top surface of a corresponding one of the mask patterns 142. The formation of the contact holes 200H may include etching portions of the protection layer 190, which are placed on the mask patterns 142, to expose the top surfaces of the mask patterns 142.

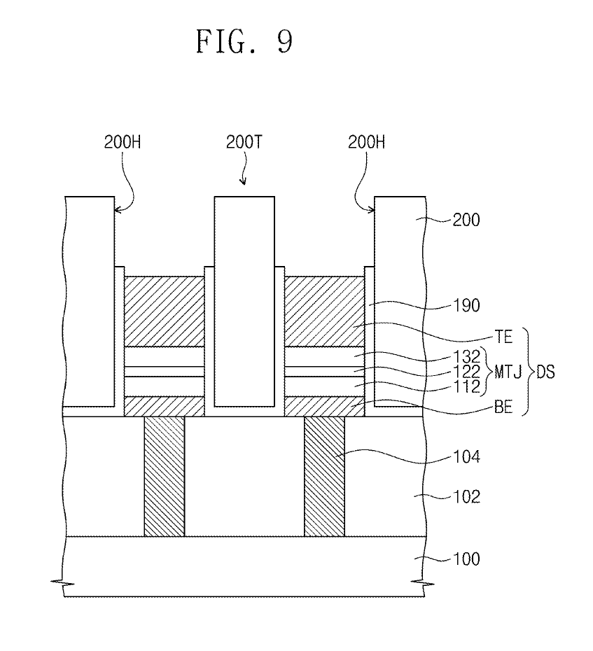

Referring to FIGS. 1 and 9, the mask patterns 142 may be removed to expose the top electrode patterns TE (operation S150). The removal of the mask patterns 142 may include selectively etching the mask patterns 142 using, for example, a wet etching process. The wet etching process may be performed using, for example, an etching solution containing nitric acid. As a result of the removal of the mask patterns 142, the top surface of each of the top electrode patterns TE may be exposed.

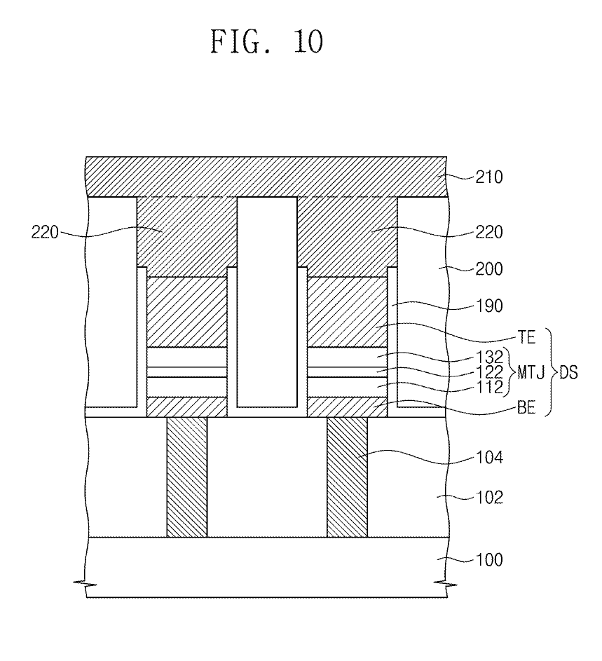

Referring to FIGS. 1 and 10, after the removal of the mask patterns 142, conductive patterns 210 and 220 connected to the top electrode patterns TE may be formed (operation S160). The conductive patterns 210 and 220 may include a conductive line 210, which is formed in the trench 200T, and conductive contacts 220, which are respectively formed in the contact holes 200H. The conductive line 210 may be a line-shaped pattern extending in the direction parallel to the top surface 100U of the substrate 100. The conductive contacts 220 may be patterns extending from the conductive line 210 in a direction toward the substrate 100 and may be connected to the top electrode patterns TE, respectively. The conductive contacts 220 may be in contact with the top electrode patterns TE, respectively. The protection layer 190 may be provided to partially cover a side surface of each of the conductive contacts 220. The conductive line 210 may be used as a bit line. The conductive line 210 may be connected to the magnetic tunnel junction patterns MTJ through the conductive contacts 220 and the top electrode patterns TE. The formation of the conductive patterns 210 and 220 may include forming a conductive layer on the upper interlayered insulating layer 200 to fill the trench 200T and the contact holes 200H and planarizing the conductive layer to expose the upper interlayered insulating layer 200.

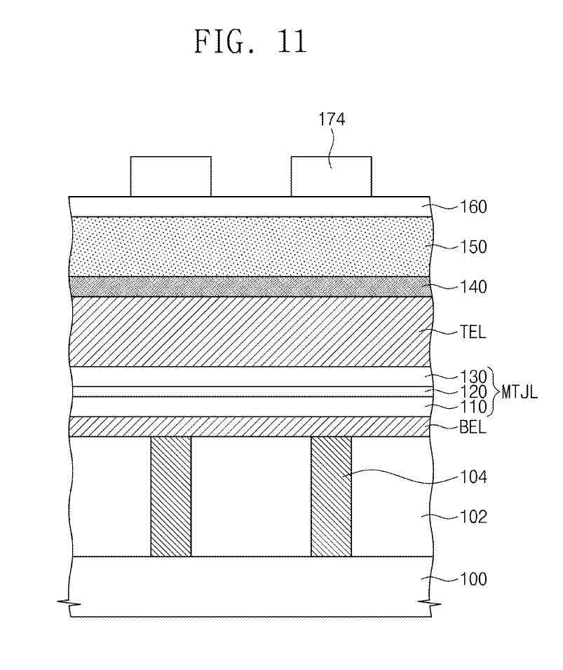

FIGS. 11 to 13 are sectional views illustrating a method of fabricating a magnetic memory device according to an example embodiment. For concise description, the following description will mainly refer to an element or feature that is different from that in the method previously described with reference to FIGS. 1 to 10.

Referring to FIGS. 1 and 11, the bottom electrode layer BEL and the magnetic tunnel junction layer MTJL may be sequentially formed on the lower interlayered insulating layer 102 (operation S100). The top electrode layer TEL, the mask layer 140, and the first preliminary mask layer 150 may be sequentially formed on the magnetic tunnel junction layer MTJL. The anti-reflection layer 160 may be formed on the first preliminary mask layer 150, and photoresist patterns 174 may be formed on the anti-reflection layer 160. The photoresist patterns 174 may be used to define positions and shapes of the magnetic tunnel junction patterns MTJ. The photoresist patterns 174 may be formed to be spaced apart from each other in a horizontal direction parallel to the top surface 100U of the substrate 100.

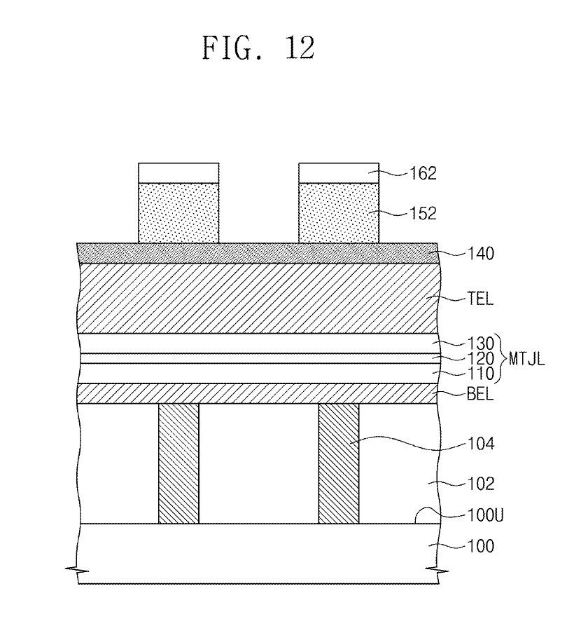

Referring to FIG. 12, the anti-reflection layer 160 and the first preliminary mask layer 150 may be etched using the photoresist patterns 174 as an etch mask. Accordingly, the anti-reflection layer 160 may be patterned to form anti-reflection patterns 162, and the first preliminary mask layer 150 may be patterned to form first preliminary mask patterns 152. The anti-reflection patterns 162 may be formed to be spaced apart from each other in a horizontal direction parallel to the top surface 100U of the substrate 100. The first preliminary mask patterns 152 may also be formed to be spaced apart from each other in the horizontal direction and may be provided below the anti-reflection patterns 162, respectively. The first preliminary mask patterns 152 may be used to define positions and shapes of the magnetic tunnel junction patterns MTJ.

Referring to FIGS. 1, 5, and 13, the mask patterns 142 and the top electrode patterns TE may be formed on the magnetic tunnel junction layer MTJL (operation S110).

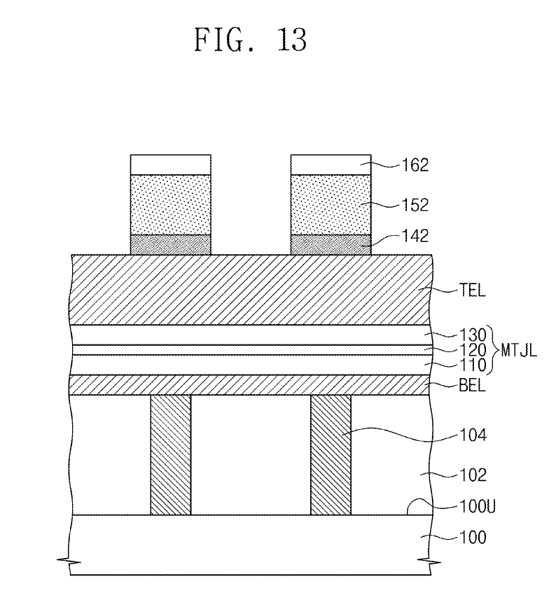

As shown in FIG. 13, the mask layer 140 may be etched using the anti-reflection patterns 162 and the first preliminary mask patterns 152 as an etch mask. Accordingly, the mask patterns 142 may be formed on the top electrode layer TEL. The anti-reflection patterns 162 and the first preliminary mask patterns 152 may be removed after the formation of the mask patterns 142. The anti-reflection patterns 162 and the first preliminary mask patterns 152 may be removed by, for example, an ashing and/or strip process.

Referring back to FIG. 5, the top electrode layer TEL may be etched using the mask patterns 142 as an etch mask, and as a result, the top electrode patterns TE may be formed on the magnetic tunnel junction layer MTJL. Each of the top electrode patterns TE may be formed to have the first thickness T1, and each of the mask patterns 142 may be formed to have the second thickness T2 that is less than the first thickness T1. The mask patterns 142 may be provided on the top electrode patterns TE, respectively.

The subsequent processes may be performed in substantially the same manner as those in the method described with reference to FIGS. 1 and 6 to 10.

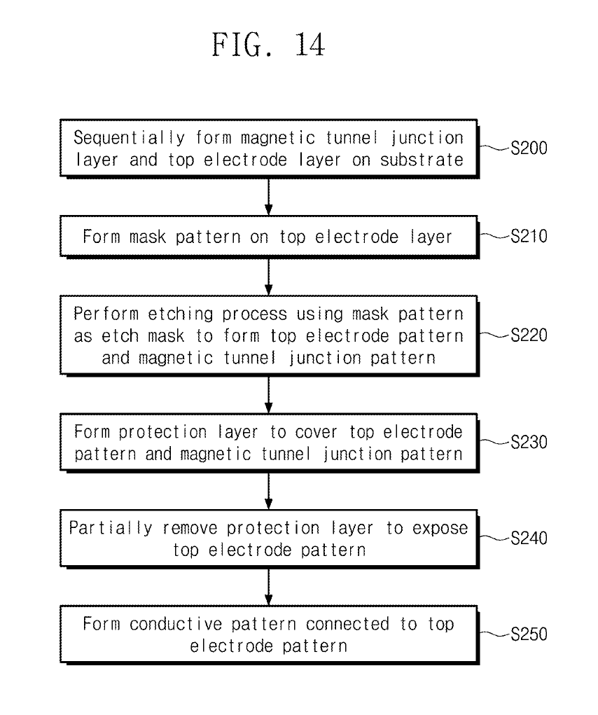

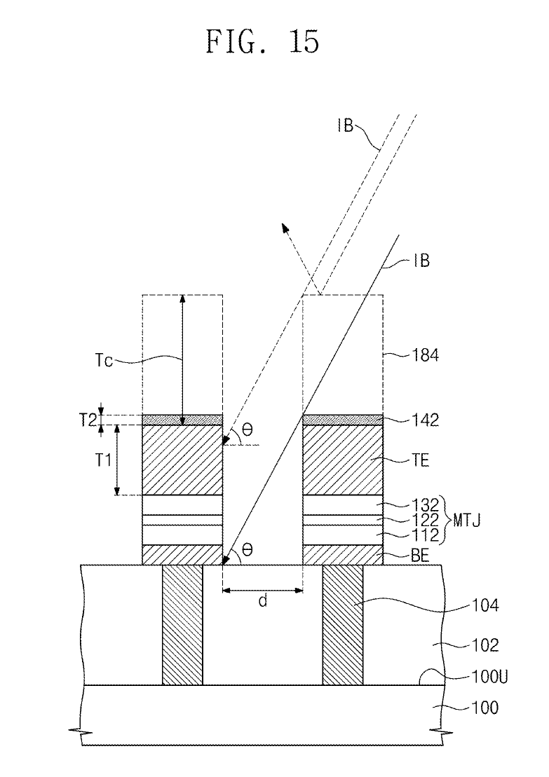

FIG. 14 is a flowchart illustrating a method of fabricating a magnetic memory device according to an example embodiment. FIGS. 15 to 18 are sectional views illustrating a method of fabricating a magnetic memory device according to an example embodiment. For concise description, the following description will mainly refer to an element or feature that is different from that in the method previously described with reference to FIGS. 1 to 10.

Referring to FIGS. 2 and 14, the bottom electrode layer BEL, the magnetic tunnel junction layer MTJL, and the top electrode layer TEL may be sequentially formed on the lower interlayered insulating layer 102 (operation S200). The mask layer 140 and the first preliminary mask layer 150 may be sequentially formed on the top electrode layer TEL. The anti-reflection layer 160 may be formed on the first preliminary mask layer 150, and the photoresist pattern 170 may be formed on the anti-reflection layer 160. The photoresist pattern 170 may include the plurality of openings 172, which will be used to define positions and shapes of the magnetic tunnel junction patterns MTJ in a subsequent process.

Referring to FIG. 3, the anti-reflection layer 160 and the first preliminary mask layer 150 may be etched using the photoresist pattern 170 as an etch mask. Accordingly, the plurality of holes H may be formed in the anti-reflection layer 160 and the first preliminary mask layer 150. After the etching of the anti-reflection layer 160 and the first preliminary mask layer 150, the photoresist pattern 170 may be removed. Thereafter, the second preliminary mask layer 180 may be formed on the anti-reflection layer 160 to fill the plurality of holes H.

Referring to FIGS. 4 and 14, the mask patterns 142 may be formed on the top electrode layer TEL (operation S210). The second preliminary mask patterns 182 may be formed on the mask layer 140. The formation of the second preliminary mask patterns 182 may include planarizing the second preliminary mask layer 180 to expose the anti-reflection layer 160 and then removing the anti-reflection layer 160 and the first preliminary mask layer 150. The second preliminary mask patterns 182 may define positions and shapes of the magnetic tunnel junction patterns MTJ in a subsequent process. The mask layer 140 may be etched using the second preliminary mask patterns 182 as an etch mask, and thus, the mask patterns 142 may be formed on the top electrode layer TEL. After the formation of the mask patterns 142, the second preliminary mask patterns 182 may be removed. The removal of the second preliminary mask patterns 182 may include selectively removing the second preliminary mask patterns 182 using, for example, a wet etching process.

Referring to FIGS. 14 and 15, an etching process using the mask patterns 142 as an etch mask may be performed to form top electrode patterns TE, magnetic tunnel junction patterns MTJ and bottom electrode patterns BE (operation S220).

In an example embodiment, the etching process may be an ion beam etching process. The ion beam etching process may include irradiating the ion beam IB onto the substrate 100. The ion beam IB may include ions of inert gas (e.g., positive argon ions (Ar+)). The top electrode layer TEL, the magnetic tunnel junction layer MTJL, and the bottom electrode layer BEL may be sequentially patterned by the ion beam etching process using the mask patterns 142 as the etch mask. Accordingly, the top electrode patterns TE, the magnetic tunnel junction patterns MTJ, and the bottom electrode patterns BE may be formed on the lower interlayered insulating layer 102. Each of the magnetic tunnel junction patterns MTJ may include the first magnetic pattern 112, the tunnel barrier pattern 122, and the second magnetic pattern 132, which are sequentially stacked on a corresponding one of the bottom electrode patterns BE.

The top electrode patterns TE may be formed of or include one or more materials, which are selected to have an etch selectivity with respect to the magnetic tunnel junction layer MTJL during the ion beam etching process. The top electrode patterns TE may be formed of or include metals (e.g., Ta, W, Ru, or Ir) and/or conductive metal nitrides (e.g., TiN). The mask patterns 142 may be formed of or include one or more materials, which are selected to have an etch selectivity with respect to the magnetic tunnel junction layer MTJL during the ion beam etching process. In addition, the mask patterns 142 may be formed of or include a material, which is higher than the top electrode patterns TE in terms of an etch selectivity with respect to the magnetic tunnel junction layer MTJL during the ion beam etching process. For example, an etch selectivity of the mask patterns 142 to the magnetic tunnel junction layer MTJL may be higher than that of the top electrode patterns TE to the magnetic tunnel junction layer MTJL. The mask patterns 142 may be formed of or include metal oxides (e.g., aluminum oxide), metal nitrides (e.g., aluminum nitride), and/or carbon-containing materials.

The mask patterns 142 may be formed to have the second thickness T2 that is less than the first thickness T1 of the top electrode patterns TE. The mask patterns 142 may be consumed and removed during the ion beam etching process.

In certain example embodiments, the etching process may include a reactive ion etching process, which is performed to form the top electrode patterns TE, and an ion beam etching process, which is performed to form the magnetic tunnel junction patterns MTJ and the bottom electrode patterns BE. The reactive ion etching process may be performed using a reactive gas for selectively etching the top electrode layer TEL, and the ion beam etching process may include irradiating the ion beam IB toward the substrate 100. In this case, the top electrode layer TEL may be patterned by the reactive ion etching process, in which the mask patterns 142 is used as an etch mask, and the magnetic tunnel junction layer MTJL and the bottom electrode layer BEL may be sequentially patterned by the ion beam etching process, in which the top electrode patterns TE and the mask patterns 142 are used as an etch mask. The mask patterns 142 may be consumed and removed during the reactive ion etching process and the ion beam etching process.

In the present example embodiments, the second thickness T2 of the mask patterns 142 may be within a range allowing the mask patterns 142 to be removed during the etching process for forming the top electrode patterns TE, the magnetic tunnel junction patterns MTJ, and the bottom electrode patterns BE. In this case, it is unnecessary to perform an additional process for removing residues of the mask patterns 142 from the top surfaces of the top electrode patterns TE.

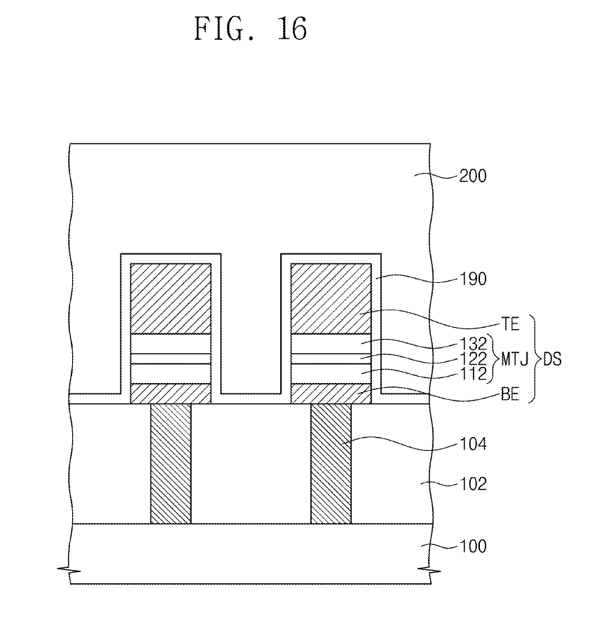

Referring to FIGS. 14 and 16, each of the bottom electrode patterns BE, each of the magnetic tunnel junction patterns MTJ, and each of the top electrode patterns TE may be referred to as “the data storage structure DS.”

The protection layer 190 may be formed on the lower interlayered insulating layer 102 to cover the top electrode patterns TE, the magnetic tunnel junction patterns MTJ, and the bottom electrode patterns BE (operation S230). The protection layer 190 may be formed to conformally cover side surfaces of the top electrode patterns TE, side surfaces of the magnetic tunnel junction patterns MTJ, and side surfaces of the bottom electrode patterns BE. In other words, the protection layer 190 may conformally cover a side surface of the data storage structure DS. The protection layer 190 may be extended to cover the top surface of each of the top electrode patterns TE and to cover the top surface of the lower interlayered insulating layer 102 between the magnetic tunnel junction patterns MTJ. The protection layer 190 may be in contact with the top surface of each of the top electrode patterns TE.

The upper interlayered insulating layer 200 may be formed on the protection layer 190 to cover the top electrode patterns TE, the magnetic tunnel junction patterns MTJ, and the bottom electrode patterns BE. The protection layer 190 may be interposed between the data storage structure DS and the upper interlayered insulating layer 200. The protection layer 190 may extend horizontally between the magnetic tunnel junction patterns MTJ to be interposed between the top surface of the lower interlayered insulating layer 102 and the upper interlayered insulating layer 200.

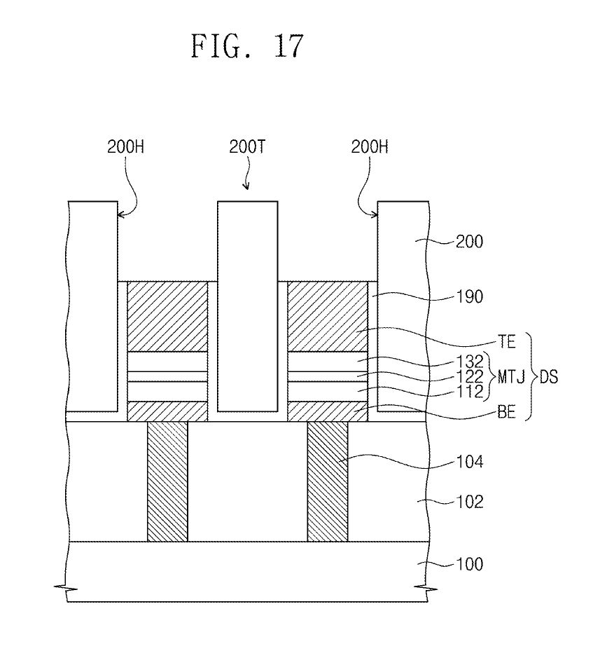

Referring to FIGS. 14 and 17, the upper interlayered insulating layer 200 and the protection layer 190 may be partially removed to expose the top electrode patterns TE (operation S240). For example, the trench 200T and the contact holes 200H may be formed in the upper interlayered insulating layer 200. The trench 200T and the contact holes 200H may be formed by etching portions of the upper interlayered insulating layer 200. The trench 200T may be formed to extend in a direction parallel to the top surface 100U of the substrate 100, and each of the contact holes 200H may be formed to extend from the trench 200T in a direction toward the substrate 100. Each of the contact holes 200H may be formed to expose a top surface of a corresponding one of the top electrode patterns TE. The formation of the contact holes 200H may include etching portions of the protection layer 190, which are placed on the top electrode patterns TE, to expose the top surfaces of the top electrode patterns TE.

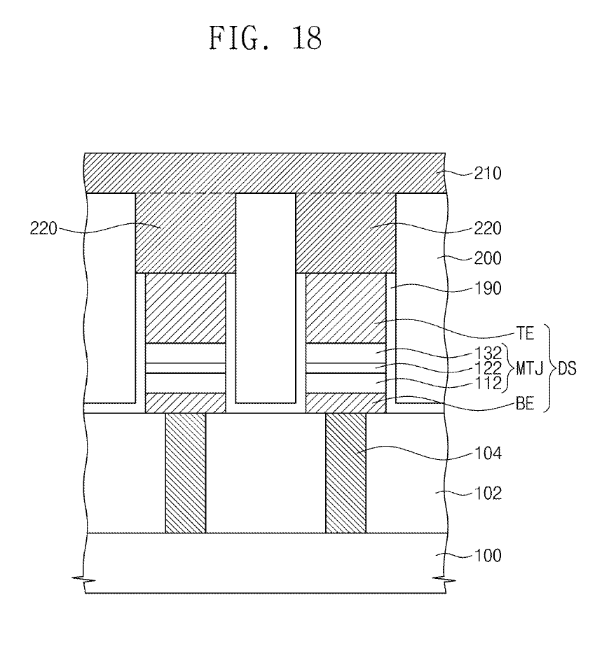

Referring to FIGS. 14 and 18, the conductive patterns 210 and 220 may be formed to be connected to the top electrode patterns TE (operation S250). The conductive patterns 210 and 220 may include the conductive line 210, which is formed in the trench 200T, and the conductive contacts 220, which are formed in the contact holes 200H, respectively. The conductive contacts 220 may be formed to be in contact with the top electrode patterns TE, respectively.

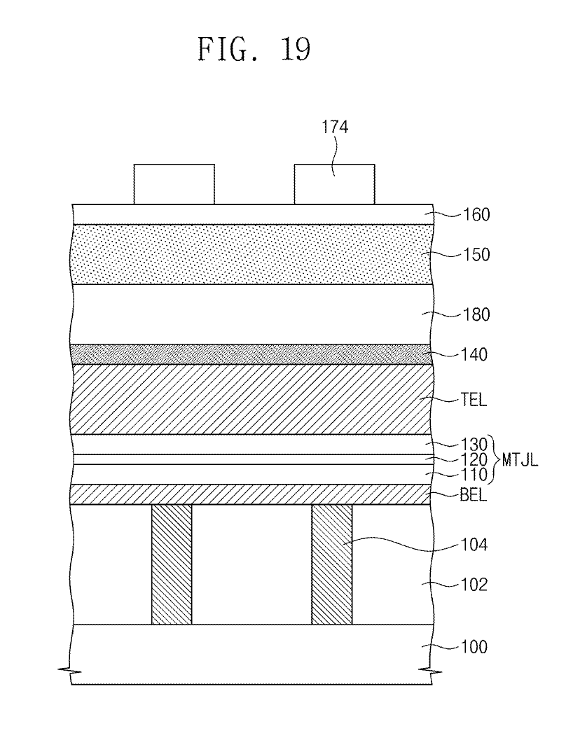

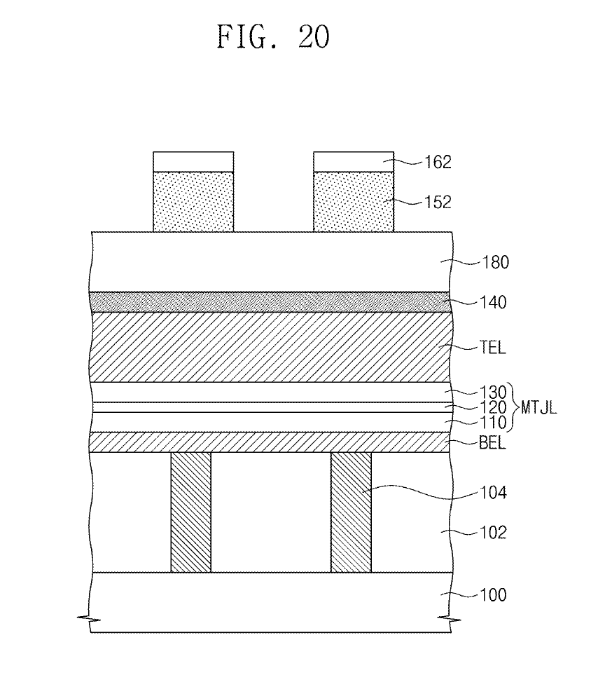

FIGS. 19 and 20 are sectional views illustrating a method of fabricating a magnetic memory device according to an example embodiment. For concise description, the following description will mainly refer to an element or feature that is different from that in the method previously described with reference to FIGS. 1 to 10.

Referring to FIGS. 14 and 19, the bottom electrode layer BEL, the magnetic tunnel junction layer MTJL, and the top electrode layer TEL may be sequentially formed on the lower interlayered insulating layer 102 (operation S200). The mask layer 140, the second preliminary mask layer 180, and the first preliminary mask layer 150 may be sequentially formed on the top electrode layer TEL. The second preliminary mask layer 180 may be formed between the mask layer 140 and the first preliminary mask layer 150. The anti-reflection layer 160 may be formed on the first preliminary mask layer 150, and the photoresist patterns 174 may be formed on the anti-reflection layer 160. The photoresist patterns 174 may be used to define positions and shapes of the magnetic tunnel junction patterns MTJ. The photoresist patterns 174 may be formed to be spaced apart from each other in a horizontal direction parallel to the top surface 100U of the substrate 100.

Referring to FIG. 20, the anti-reflection layer 160 and the first preliminary mask layer 150 may be etched using the photoresist patterns 174 as an etch mask. Accordingly, the anti-reflection layer 160 may be patterned to form the anti-reflection patterns 162, and the first preliminary mask layer 150 may be patterned to form the first preliminary mask patterns 152. The anti-reflection patterns 162 may be horizontally spaced apart from each other. The first preliminary mask patterns 152 may be respectively provided below the anti-reflection patterns 162 and may be horizontally spaced apart from each other. The first preliminary mask patterns 152 may be used to define positions and shapes of the magnetic tunnel junction patterns MTJ.

Referring to FIGS. 4 and 14, the mask patterns 142 may be formed on the top electrode layer TEL (operation S210). The second preliminary mask patterns 182 may be formed on the mask layer 140. The formation of the second preliminary mask patterns 182 may include performing an etching process, in which the anti-reflection patterns 162 and the first preliminary mask patterns 152 are used as an etch mask, to pattern the second preliminary mask layer 180. After the formation of the second preliminary mask patterns 182, the anti-reflection patterns 162 and the first preliminary mask patterns 152 may be removed. The anti-reflection patterns 162 and the first preliminary mask patterns 152 may be removed by, for example, an ashing and/or strip process.

The mask layer 140 may be etched using the second preliminary mask patterns 182 as an etch mask, and thus, the mask patterns 142 may be formed on the top electrode layer TEL. After the formation of the mask patterns 142, the second preliminary mask patterns 182 may be removed. The removal of the second preliminary mask patterns 182 may include selectively removing the second preliminary mask patterns 182 using, for example, a wet etching process.

The subsequent processes may be performed in substantially the same manner as those in the method described with reference to FIGS. 14 to 18.

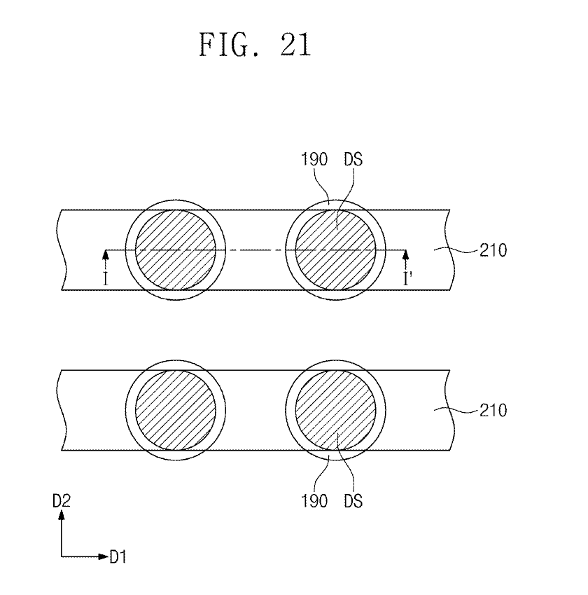

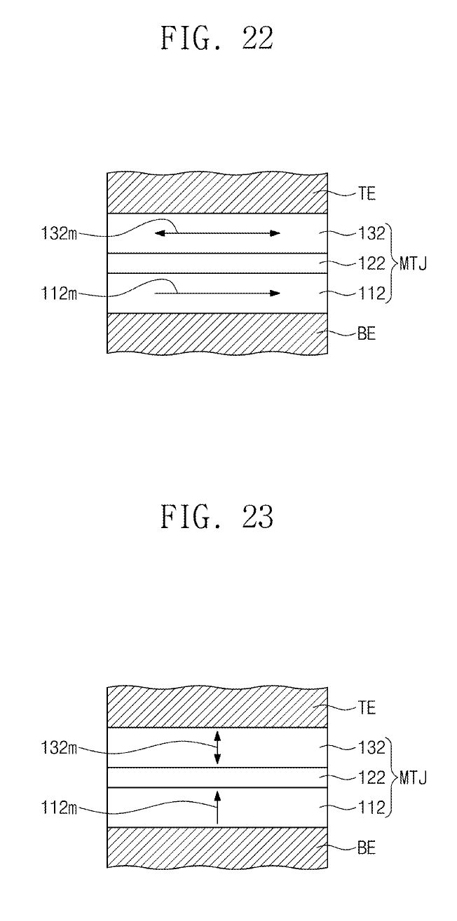

FIG. 21 is a plan view of a magnetic memory device fabricated by a method according to an example embodiment. FIG. 10 corresponds to a sectional view taken along line I-I′ of FIG. 21. FIGS. 22 and 23 are sectional views illustrating examples of a magnetic tunnel junction pattern of a magnetic memory device fabricated by a method according to an example embodiment.

Referring to FIGS. 10 and 21, the lower interlayered insulating layer 102 may be provided on the substrate 100. The selection elements may be provided on the substrate 100, and the lower interlayered insulating layer 102 may be provided to cover the selection elements. The lower contact plugs 104 may be provided in the lower interlayered insulating layer 102 and may be connected to the substrate 100. Each of the lower contact plugs 104 may be provided to penetrate the lower interlayered insulating layer 102 and may be electrically connected to a terminal of a corresponding one of the selection elements.

The data storage structures DS may be provided on the lower interlayered insulating layer 102. When viewed in a plan view, the data storage structures DS may be two-dimensionally arranged in first and second directions D1 and D2, which are not parallel to each other. The data storage structures DS may be connected to the lower contact plugs 104, respectively. Each of the data storage structures DS may include the magnetic tunnel junction pattern MTJ, the bottom electrode pattern BE between a corresponding one of the lower contact plugs 104 and the magnetic tunnel junction pattern MTJ, and the top electrode pattern TE spaced apart from the bottom electrode pattern BE with the magnetic tunnel junction pattern MTJ interposed therebetween. The magnetic tunnel junction pattern MTJ may be provided between the bottom electrode pattern BE and the top electrode pattern TE. Each of the bottom electrode patterns BE may be in direct contact with a corresponding one of the lower contact plugs 104.

The magnetic tunnel junction pattern MTJ may include the first magnetic pattern 112, the second magnetic pattern 132, and the tunnel barrier pattern 122 therebetween. The first magnetic pattern 112 may be provided between the bottom electrode pattern BE and the tunnel barrier pattern 122, and the second magnetic pattern 132 may be provided between the top electrode pattern TE and the tunnel barrier pattern 122. The tunnel barrier pattern 122 may be formed of or include magnesium oxide, titanium oxide, aluminum oxide, magnesium-zinc oxide, and/or magnesium-boron oxide. Each of the first magnetic pattern 112 and the second magnetic pattern 132 may include at least one magnetic layer.

Referring to FIGS. 22 and 23, the first magnetic pattern 112 may include a reference layer, whose magnetization direction 112m is fixed to a specific direction, and the second magnetic pattern 132 may include a free layer, whose magnetization direction 132m can be changed to be parallel or anti-parallel (e.g., parallel but oppositely directed or oriented) to the magnetization direction 112m of the reference layer. FIGS. 22 and 23 illustrate an example in which the first and second magnetic patterns 112 and 132 are configured to include the reference and free layers, respectively, but the present disclosure is not limited thereto. For example, the first and second magnetic patterns 112 and 132 may be configured to include the free and reference layers, respectively, unlike what is shown in FIGS. 22 and 23.

In an example embodiment, as shown in FIG. 22, the magnetization directions 112m and 132m may be substantially parallel to an interface between the tunnel barrier pattern 122 and the first magnetic pattern 112. In this case, each of the reference layer and the free layer may be formed of or include a ferromagnetic material. The reference layer may further include an anti-ferromagnetic material for fixing a magnetization direction of the ferromagnetic material.

In certain embodiments, as shown in FIG. 23, the magnetization directions 112m and 132m may be substantially perpendicular to the interface between the tunnel barrier pattern 122 and the first magnetic pattern 112. In this case, each of the reference layer and the free layer may include perpendicular magnetic materials (e.g., CoFeTb, CoFeGd, and CoFeDy), perpendicular magnetic materials with L1₀ structure, CoPt-based materials with hexagonal-close-packed structure, and/or perpendicular magnetic structures. The perpendicular magnetic material with the L1₀ structure may include at least one of L1₀ FePt, L1₀ FePd, L1₀ CoPd, or L1₀ CoPt. The perpendicular magnetic structures may include magnetic layers and non-magnetic layers that are alternatingly and repeatedly stacked. For example, the perpendicular magnetic structures may include at least one of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n, where n denotes the number of stacked layer pairs. Here, the reference layer may be thicker than the free layer or may be configured to have a coercive force greater than that of the free layer.

Referring back to FIGS. 10 and 21, the upper interlayered insulating layer 200 may be provided on the lower interlayered insulating layer 102. The upper interlayered insulating layer 200 may be provided to cover the data storage structures DS. Each of the data storage structures DS may be provided to penetrate the upper interlayered insulating layer 200 and may be connected to a corresponding one of the lower contact plugs 104. The protection layer 190 may be interposed between each of the data storage structures DS and the upper interlayered insulating layer 200. The protection layer 190 may be provided to surround the side surface of each of the data storage structures DS and may be extended to cover the top surface of the lower interlayered insulating layer 102 between the data storage structures DS. The protection layer 190 may be provided to surround the side surfaces of the bottom electrode pattern BE, the magnetic tunnel junction pattern MTJ, and the top electrode pattern TE.

The conductive contacts 220 may be provided on the data storage structures DS, respectively. Each of the conductive contacts 220 may be provided to penetrate at least a portion of the upper interlayered insulating layer 200 and may be connected to the top electrode pattern TE of a corresponding one of the data storage structures DS. Each of the conductive contacts 220 may be in direct contact with the top electrode pattern TE of a corresponding one of the data storage structures DS. The protection layer 190 may be extended from the side surface of the top electrode pattern TE to at least partially cover side surfaces of the conductive contacts 220. When viewed in a plan view, a portion of the side surface of each of the conductive contacts 220 may be surrounded by the protection layer 190. The protection layer 190 may be interposed between the portion of the side surface of each of the conductive contacts 220 and the upper interlayered insulating layer 200. Other portions of the side surface of each of the conductive contacts 220 may be in contact with the upper interlayered insulating layer 200.

The conductive line 210 may be provided on the upper interlayered insulating layer 200. The conductive line 210 may extend in the first direction D1 and may be connected in common to the data storage structures DS arranged in the first direction D1. A plurality of the conductive lines 210 may be provided to be spaced apart from each other in the second direction D2. Each of the data storage structures DS may be connected to a corresponding one of the conductive lines 210 through a corresponding one of the conductive contacts 220.

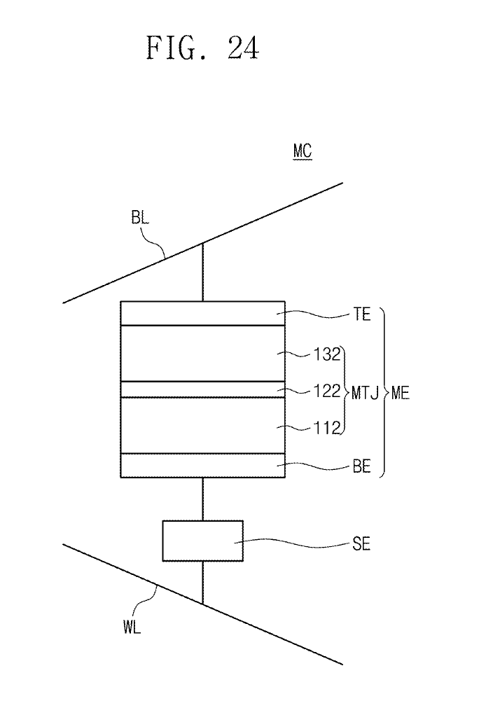

FIG. 24 is a circuit diagram illustrating a unit memory cell of a magnetic memory device fabricated by a method according to an example embodiment.

Referring to FIG. 24, a unit memory cell MC may include a memory element ME and a selection element SE. The memory element ME may be provided between and connected to a bit line BL and the selection element SE, and the selection element SE may be provided between and connected to the memory element ME and a word line WL. The memory element ME may be a variable resistance device, whose resistance can be switched to one of at least two states by an electric pulse applied thereto. In an example embodiment, the memory element ME may be provided to have a layered structure, whose electric resistance can by changed by a spin transfer process using an electric current passing therethrough. For example, the memory element ME may have a layered structure, which is configured to exhibit a magneto-resistance property, and may include at least one ferromagnetic material and/or at least one antiferromagnetic material. The selection element SE may be configured to selectively control a current flow of an electric current passing through the memory element ME. As an example, the selection element SE may be one of a diode, a PNP bipolar transistor, an NPN bipolar transistor, an n-channel metal-oxide-semiconductor (NMOS) field effect transistor, and a p-channel metal-oxide-semiconductor PMOS field effect transistor. In the case where the selection element SE is a three-terminal device (e.g., a bipolar transistor or a MOS field effect transistor), an additional interconnection line may be connected to the selection element SE.

The memory element ME may include the first magnetic pattern 112, the second magnetic pattern 132, and the tunnel barrier pattern 122 therebetween. The first magnetic pattern 112, the second magnetic pattern 132, and the tunnel barrier pattern 122 may constitute the magnetic tunnel junction pattern MTJ. Each of the first and second magnetic patterns 112 and 132 may include at least one magnetic layer that is formed of a magnetic material. The memory element ME may further include the bottom electrode pattern BE, which is interposed between the first magnetic pattern 112 and the selection element SE, and the top electrode pattern TE, which is interposed between the second magnetic pattern 132 and the bit line BL.

According to an example embodiment, the mask patterns 142 may be used as an etch mask in the ion beam etching process for forming the magnetic tunnel junction patterns MTJ. The mask patterns 142 may be provided to have the second thickness T2, which is less than the first thickness T1 of the top electrode patterns TE, and may be formed of or include a material, whose etch selectivity with respect to the magnetic tunnel junction layer MTJL is higher than that of the top electrode patterns TE, during the ion beam etching process. Since the mask patterns 142 have a relatively small thickness, it may be possible to prevent or suppress the ion beam IB from being blocked by the mask patterns 142 during the ion beam etching process, even when the distance d between the magnetic tunnel junction patterns MTJ is reduced. Accordingly, it may be possible to effectively and easily remove the conductive etch residue from side surfaces of the magnetic tunnel junction patterns MTJ and to more easily etch the magnetic tunnel junction layer MTJL and the bottom electrode layer BEL. In addition, since the mask patterns 142 include a material with a relatively high etch selectivity, it may be possible to stably etch the magnetic tunnel junction layer MTJL and the bottom electrode layer BEL during the ion beam etching process.

According to an example embodiment, magnetic tunnel junction patterns may be formed by an ion beam etching process using mask patterns as an etch mask. The mask patterns may be formed to have a relatively small thickness, and thus, it may be possible to suppress or prevent an ion beam from being blocked by the mask patterns during the ion beam etching process. Accordingly, a conductive etch residue on side surfaces of the magnetic tunnel junction patterns may be easily removed by the ion beam etching process, and a magnetic tunnel junction layer and a bottom electrode layer may be easily patterned by the ion beam etching process. In addition, the mask patterns include a material having relatively high etch selectivity, and this may make it possible to stably etch the magnetic tunnel junction layer and the bottom electrode layer through the ion beam etching process.

While example embodiments have been particularly shown and described, it will be understood by one of ordinary skill in the art that variations in form and detail may be made therein without departing from the spirit and scope of the attached claims.

1. A method of fabricating a magnetic memory device, the method comprising:
forming a magnetic tunnel junction layer on a substrate;
sequentially forming a top electrode pattern and a mask pattern on the magnetic tunnel junction layer;
patterning the magnetic tunnel junction layer using the mask pattern and the top electrode pattern as a first etch mask to form a magnetic tunnel junction pattern;
forming a protection layer on side surfaces of the mask pattern, the top electrode pattern, and the magnetic tunnel junction pattern, the protection layer being extended to cover a first top surface of the mask pattern;
removing a portion of the protection layer on the first top surface of the mask pattern to expose the first top surface of the mask pattern; and
removing the mask pattern to expose a second top surface of the top electrode pattern.

2. The method of claim 1, wherein the forming the magnetic tunnel junction pattern comprises patterning the magnetic tunnel junction layer using an ion beam etching process, in which the mask pattern and the top electrode pattern are used as the first etch mask, and
wherein the mask pattern comprises a first material different from a second material of the top electrode pattern.

3. The method of claim 2, wherein the mask pattern comprises at least one of metal oxides, metal nitrides, and carbon-containing materials.

4. The method of claim 2, wherein a first etch selectivity of the first material with respect to the magnetic tunnel junction layer is higher than a second etch selectivity of the second material with respect to the magnetic tunnel junction layer, during the ion beam etching process.

5. The method of claim 2, wherein the mask pattern is formed to have a first thickness less than a second thickness of the top electrode pattern.

6. The method of claim 2, wherein the ion beam etching process is performed using an ion beam, which is irradiated at an oblique angle to a third top surface of the substrate.

7. The method of claim 6, wherein the ion beam comprises ions of inert gas.

8. The method of claim 1, further comprising:
forming an interlayered insulating layer on the protection layer to cover the mask pattern, the top electrode pattern, and the magnetic tunnel junction pattern; and
forming a contact hole in the interlayered insulating layer to expose the portion of the protection layer on the first top surface of the mask pattern,
wherein the removing of the portion of the protection layer comprises removing the portion of the protection layer exposed by the contact hole.

9. The method of claim 8, further comprising forming a conductive contact in the contact hole, after the removing the mask pattern,
wherein the conductive contact is in contact with the top electrode pattern.

10. The method of claim 1, wherein the removing the mask pattern comprises selectively etching the mask pattern using a wet etching process.

11. The method of claim 1, wherein the sequentially forming the top electrode pattern and the mask pattern comprises:
sequentially forming a top electrode layer and a mask layer on the magnetic tunnel junction layer;
forming a preliminary mask pattern on the mask layer;
etching the mask layer using the preliminary mask pattern as a second etch mask to form the mask pattern; and
etching the top electrode layer using the preliminary mask pattern and the mask pattern as a third etch mask to form the top electrode pattern,
wherein the preliminary mask pattern is removed during at least one of the etching of the top electrode layer and during the patterning of the magnetic tunnel junction layer.

12. The method of claim 11, wherein the preliminary mask pattern comprises oxide.

13. The method of claim 1, wherein the sequentially forming the top electrode pattern and the mask pattern comprises:
sequentially forming a top electrode layer and a mask layer on the magnetic tunnel junction layer;
forming a preliminary mask pattern on the mask layer;
etching the mask layer using the preliminary mask pattern as a second etch mask to form the mask pattern;
removing the preliminary mask pattern; and
etching the top electrode layer using the mask pattern as a third etch mask to form the top electrode pattern.

14. The method of claim 13, wherein the preliminary mask pattern comprises a carbon-containing material.

15. The method of claim 1, further comprising forming a conductive contact on the second top surface of the top electrode pattern, after the removing the mask pattern,
wherein the protection layer covers a portion of a side surface of the conductive contact.

16. A method of fabricating a magnetic memory device, the method comprising:
sequentially forming a magnetic tunnel junction layer, a top electrode layer, and a mask layer on a substrate, the top electrode layer being interposed between the magnetic tunnel junction layer and the mask layer;
forming a preliminary mask pattern on the mask layer;
patterning the mask layer using the preliminary mask pattern as a first etch mask to form a mask pattern;
removing the preliminary mask pattern; and
patterning the top electrode layer and the magnetic tunnel junction layer using the mask pattern as a second etch mask,
wherein the mask pattern is removed during the patterning the top electrode layer and the magnetic tunnel junction layer.

17. The method of claim 16, wherein the patterning the top electrode layer and the magnetic tunnel junction layer comprises performing an ion beam etching process, in which the mask pattern is used as the second etch mask, to sequentially etch the top electrode layer and the magnetic tunnel junction layer.

18. The method of claim 17, wherein the top electrode layer comprises a first material having a first etch selectivity with respect to the magnetic tunnel junction layer, during the ion beam etching process, and
wherein the mask pattern comprises a second material having a second etch selectivity with respect to the magnetic tunnel junction layer, the second etch selectivity being higher than the first etch selectivity, during the ion beam etching process.

19. The method of claim 17, wherein the mask pattern comprises a first material, and the first material includes at least one of metal oxides, metal nitrides, and carbon-containing materials, and
wherein the top electrode layer comprises a second material different from the first material of the mask pattern.

20. The method of claim 17, wherein the mask pattern is formed to have a first thickness less than a second thickness of the top electrode layer.

21-27. (canceled)
